(19) United States
(12) Patent Application Publication
(10) Pub. No.: US 2007/0032632 A1
(43) Pub. Date: Feb. 8, 2007

(54) Electroluminescence polymer, organic el device, and display

(75) Inventors: Miyuki Tsukioka, Tochigi (JP); Tomoyasu Sunaga, Tochigi (JP); Junichi Ishii, Tochigi (JP); Susumu Yanagibori, Tochigi (JP)

Correspondence Address: OLIFF & BERRIDGE, PLC, P.O. BOX 19928, ALEXANDRIA, VA, 22320, US

(73) Assignee: SONY CHEMICALS CORP., TOKYO (JP)

(21) Appl. No.: 10/567,124

(22) PCT Filed: Aug. 4, 2004
(86) PCT No.: PCT/JP04/11175

§ 371 Date: Feb. 6, 2006

(30) Foreign Application Priority Data
Aug. 14, 2003 (JP) 2003-293584

(51) Int. Cl. C08G 61/00; C09K 11/06; H01L 51/54; H05B 33/14

(52) U.S. Cl. 528/394; 428/690; 428/917; 313/504; 257/40; 257/E51.032; 257/E51.036; 528/397; 528/422; 528/423

(57) ABSTRACT

A novel electroluminescence polymer offers stable EL characteristics: it forms little aggregates and is less susceptible to morphological changes during and after film formation. The EL polymer comprises a binaphthyl derivative structural unit represented by the following formula (1a) and an aryl structural unit represented by the following formula (1b): 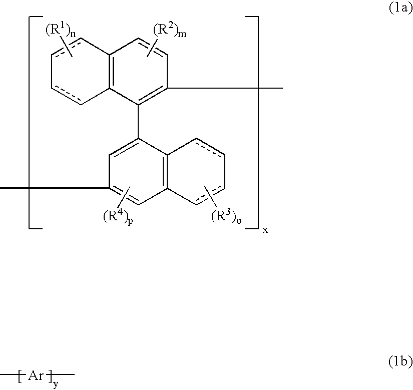
wherein Ar is an aryl structural unit that can form an electroluminescent π-conjugated polymer; R¹, R², R³, and R⁴ are each independently a different functional group; the double bonds of the binaphthyl structural unit indicated by dashed lines and solid lines are each an unsaturated double bond or a saturated single bond; m and p are each independently an integer of 0 to 2; n and o are each independently an integer of 0 to 8; x is the molar fraction of the binaphthyl derivative structural units; and y is the molar fraction of the aryl structural units.

### TECHNICAL FIELD

The present invention relates to EL polymers suitable as a material for luminescent layers of organic electroluminescence (EL) devices, as well as to such organic EL devices using the EL polymers and displays using the organic EL devices.

### BACKGROUND ART

π-conjugated polymers such as poly(paraphenylene vinylene) (PPV), poly(paraphenylene) (PPP) and poly(9,9-dialkylfluorene) (PDAF) have been used as organic EL materials to make luminescent layers used in organic EL devices (Y. Ohmori et al, Jpn. J. Appl. Phys., 1991, 30, L1941).

However, these π-conjugated polymers contain aromatic rings in a very large proportions therein and are not highly soluble in organic solvents. For this reason, simple film formation techniques, such as spin coating and different printing techniques (e.g., ink jet printing), may not be used to form films of these π-conjugated polymers.

Several attempts have been made to effectively form films of these π-conjugated polymers. Among such attempts are (1) to form films of a soluble precursor thereof soluble in solvents and subsequently convert the precursor to the desired π-conjugated polymer; (2) to introduce certain solubility-imparting organic functional groups, such as alkyl and alkoxyl groups, into the side chain of a desired π-conjugated polymer to increase the solubility of the polymer in solvents; and (3) to introduce, for example, 2,2′-biphenylene “bend” structural units into the backbone of a desired π-conjugated polymer to introduce bends in the backbone of the π-conjugated polymer, thus increasing the solubility of the polymer into solvents (Published Japanese translation of PCT application No. 2002-527554).

However, the formation of films of soluble precursor (1) results in formation of dissociated components that can cause defects in the resulting films. In addition, this technique involves undesirably many steps.

The introduction of solubility-imparting organic functional groups (2) and the introduction of bends (3) are each associated with the formation of liquid crystal phases and molecular complexes and other aggregates, which leads to a red-shift of the wavelength of the emitted light. Furthermore, each of these approaches brings about changes in the thermal properties of the polymer (for example, decrease in the glass transition point). Not only can these changes in the thermal properties of the polymer cause color shift depending on the type of aggregates formed during film formation, but they also cause changes in the morphology of the π-conjugated polymers in the formed film, depending on operation environment. As a result, color variation of the emitted light may occur and the life of the device may be decreased. These are serious problems associated with the use of π-conjugated polymers in car-mounted indicators and displays, which are intended for use in automobiles and are often exposed to very high temperature environment.

### DISCLOSURE OF THE INVENTION

Accordingly, it is an objective of the present invention to provide a novel EL polymer that forms little aggregates upon film formation, is less susceptible to morphological changes (such as formation of liquid crystal phase, intermolecular complexes and other aggregates) following film formation, and shows stable EL characteristics. It is another objective of the present invention to provide an organic EL device and a display that use the EL device.

The present inventors have discovered that by introducing binaphthyl derivative structural units into the backbone of an electroluminescent π-conjugated polymer, (i) bends can be introduced into the π-conjugated polymer, and (ii) despite the expectation that a polymer that has bends in it generally has a decreased glass transition point, the steric hindrance caused by the binaphthyl derivative structural units helps keeping the glass transition point high and significantly stabilizes the morphology of the polymer. It is this discovery that led to the present invention.

Accordingly, the present invention provides an EL polymer that comprises a binaphthyl derivative structural unit represented by the following formula (1a) and an aryl structural unit represented by the following formula (1b):

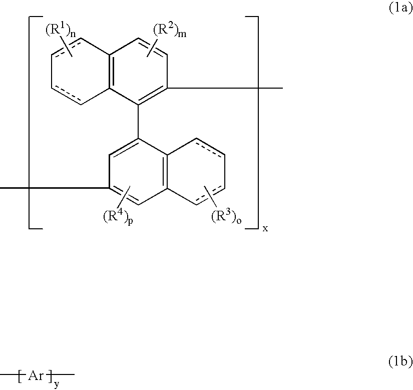

wherein Ar is an aryl structural unit that can form an electroluminescent π-conjugated polymer; R¹, R², R³ and R⁴ are each independently hydrogen, alkyl, alkenyl, alkynyl, aralkyl, aryl, heteroaryl, alkoxyl, aryloxy or aliphatic heterocyclic group; the double bonds of the binaphthyl derivative structural unit indicated by dashed lines and solid lines are each an unsaturated double bond or a saturated single bond; m and p are each independently 0, 1, or 2; n and o are each independently 0, 1, 2, 3, 4, 5, 6, 7 or 8; when m, n, o or p is an integer of 2 or greater, the two or more R¹s, R²s, R³s or R⁴s may or may not be identical to one another; x is the molar fraction of the binaphthyl derivative structural units; and y is the molar fraction of the aryl structural units.

The present invention also provides an organic EL device comprising a luminescent layer of the EL polymer sandwiched between a pair of electrodes, as well as a display comprising such an organic EL device.

According to the present invention, there is provided a novel EL polymer that forms little aggregates upon film formation, is less susceptible to morphological changes following film formation, and shows stable EL characteristics.

### BRIEF DESCRIPTION OF THE DRAWINGS

FIG. 1A is a diagram showing the results of differential scanning calorimetry of an EL polymer of Example 1.

FIG. 1B is a diagram showing the results of differential scanning calorimetry of an EL polymer of Comparative Example 1.

FIG. 2A is an EL spectrum of the EL polymer of Example 1.

FIG. 2B is an EL spectrum of the EL polymer of Comparative Example 1.

FIG. 3 is a diagram showing the relationship between the efficiency of EL luminescence and applied voltage in organic EL devices using EL polymers of Example 1 and Comparative Example 2.

### BEST MODE FOR CARRYING OUT THE INVENTION

The present invention will now be described in detail.

The EL polymer of the present invention has the structural units represented by the above-described formulas (1a) and (1b), in particular binaphthyl derivative structural units represented by the formula (1a). Specifically, the EL polymer of the present invention has a structure in which the aryl structural units of the formula (1b) are bound to position 2 and position 2′ of 1,1′-binaphthyl unit as shown by the formula (4) below. The aryl structural units are electroluminescent and can form a highly rigid (linear) π-conjugated polymer.

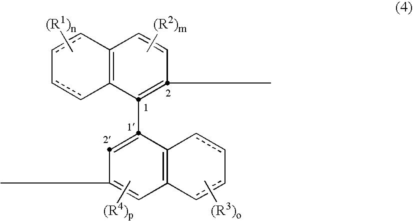

This structure results in the formation of twists in the backbone of the EL polymer of the present invention, which enables a conformation in which the interaction among polymer backbones is very weak. Furthermore, the steric hindrance caused by the naphthalene rings prevents rotation about the single bond between position 1 and position 1′, so that the glass transition point of the polymer remains high despite the bent polymer backbone (incorporating bends). As a result, the EL polymer of the present invention retains highly stable morphology during and after film formation and has highly stable EL characteristics.

In the formula (1a), R¹, R², R³ and R⁴ in the binaphthyl derivative structural unit may or may not be identical to one another and are each independently hydrogen, alkyl, alkenyl, alkynyl, aralkyl, aryl, heteroaryl, alkoxyl, aryloxy or aliphatic heterocyclic group. The alkyl group may be a straight-chained, branched or cyclic alkyl. Examples thereof include t-butyl, cyclohexyl, 2-ethylhexyl and n-octyl. The alkenyl group may be a straight-chained, branched or cyclic alkenyl. Examples thereof include propenyl. The alkynyl group may be a straight-chained, branched or cyclic alkynyl. Examples thereof include ethynyl. Examples of the aralkyl group include benzyl. Examples of the aryl group include phenyl, naphthyl, anthryl, and pyranyl. The heteroaryl group comprises an aromatic ring with a non-carbon element (such as nitrogen atom, sulfur atom and/or oxygen atom) forming part of the ring. Examples include pyridyl, thienyl, and carbazolyl. Examples of the alkoxyl group include methoxy and isopropoxy. Examples of the aryloxy group include phenoxy and naphthoxy. Examples of the aliphatic heterocyclic group include piperidyl.

The double bonds in the binaphthyl derivative structural unit of the formula (1a) indicated by dashed lines and solid lines may be unsaturated double bonds or saturated single bonds. The double bonds, however, are preferably unsaturated double bonds in terms of the efficiency of luminescence.

In the formula (1a), m and p are each independently 0, 1, or 2, as described above. n and o are each independently 0, 1, 2, 3, 4, 5, 6, 7 or 8. When m, n, o or p is an integer of 2 or greater, the two or more R¹s, R²s, R³s or R⁴s may or may not be identical to one another. For example, when there are three R¹s, they may or may not be identical to one another. When n or o is an integer of 5 or greater, the double bonds in the binaphthyl derivative structural unit of the formula (1a) indicated by dashed lines and solid lines are always saturated single bonds.

One form of the binaphthyl derivative structural unit of the formula (1a) is preferably shown by the following formula (2) in terms of the efficiency of luminescence:

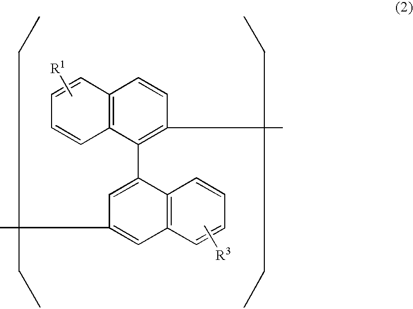

wherein R¹ and R³ are as described above. Of the compounds shown by the formula (2), ones in which R¹ and R³ are each hydrogen are particularly preferred because of their availability.

Ar in the formula (1b) is an aryl structural unit that can form an electroluminescent π-conjugated polymer. Among such aryl structural units are fluorene derivative structural units, carbazole derivative structural units, anthracene derivative structural units, naphthyl derivative structural units, biphenyl derivative structural units, benzene derivative structural units, and aromatic heterocyclic derivative structural units, as specifically shown below:

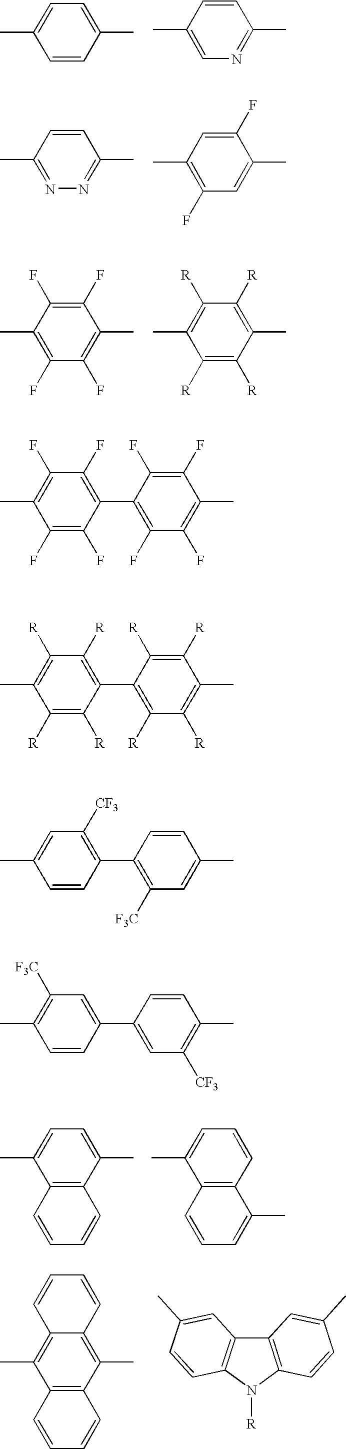

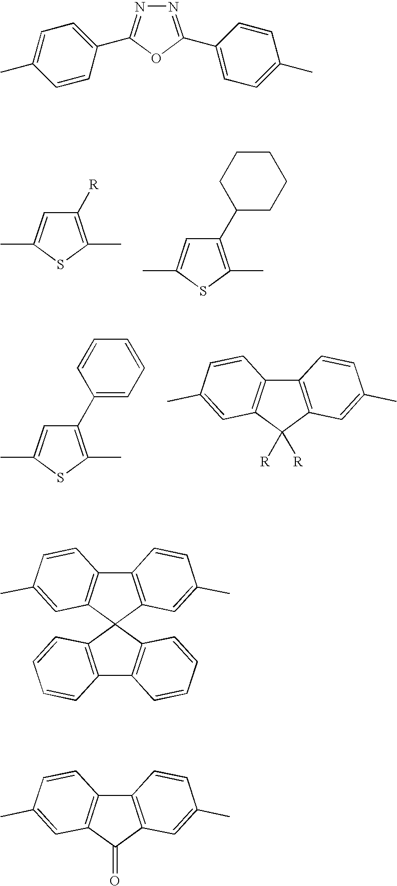

wherein R is the same as R¹ defined above.

In terms of the efficiency of luminescence, the fluorene derivative structural units represented by the following formula (3) are particularly preferred aryl structural units among those shown by the formula (1b):

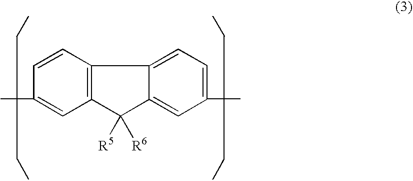

In the above formula, R⁵ and R⁶ may or may not be identical to one another and are each independently hydrogen, alkyl, alkenyl, alkynyl, aralkyl, aryl, heteroaryl, alkoxyl, aryloxy or aliphatic heterocyclic group. The alkyl group may be a straight-chained, branched, or cyclic alkyl. Examples thereof include t-butyl, cyclohexyl, 2-ethylhexyl, and n-octyl. The alkenyl group may be a straight-chained, branched or cyclic alkenyl. Examples thereof include propenyl. The alkynyl group may be a straight-chained, branched or cyclic alkynyl. Examples thereof include ethynyl. Examples of the aralkyl group include benzyl. Examples of the aryl group include phenyl, naphthyl, anthryl, and pyranyl. Examples of the heteroaryl group include an aromatic ring with a non-carbon element (such as nitrogen atom, sulfur atom and/or oxygen atom) forming part of the ring. Examples thereof include pyridyl, thienyl, and carbazolyl. Examples of the alkoxyl group include methoxy and isopropoxy. Examples of the aryloxy group include phenoxy and naphthoxy. Examples of the aliphatic heterocyclic group include piperidyl.

The EL polymer of the present invention may be a copolymer composed of three or more components including the binaphthyl derivative structural unit and the fluorene derivative structural unit, and at least one selected from carbazole derivative structural units, anthracene derivative structural units, naphthyl derivative structural units, biphenyl derivative structural units, benzene derivative structural units, and aromatic heterocyclic derivative structural units.

In the formula (1a) or (1b), x is the molar fraction of the binaphthyl derivative structural units and y is the molar fraction of the aryl structural units in the EL polymer. If x is too small, then the color stability of the polymer is affected, whereas if x is too large, then the luminescence efficiency of the polymer may be decreased. Thus, x lies preferably in the range of 0.1 to 90 mol %, and more preferably in the range of 5 to 50 mol %. On the other hand, if y is too small, then the luminescence efficiency of the polymer may be decreased, whereas if y is too large, then the color stability of the polymer may be affected. Thus, y lies preferably in the range of 10 to 99.9 mol %, and more preferably in the range of 50 to 95 mol %.

As far as the weight average molecular weight of the EL polymer of the present invention is concerned, formation of uniform film becomes difficult and the strength of the film is reduced if the weight average molecular weight of the polymer is too small, whereas the polymer with too large a weight average molecular weight is difficult to purify, readily gelates, and is less soluble in solvents. Thus, the weight average molecular weight of the EL polymer falls preferably in the range of 3,000 to 1,000,000, and more preferably in the range of 5,000 to 500,000.

In terms of the control of molecular weight and efficiency of luminescence, it is preferred that the EL polymer of the present invention be end-capped on one or both ends with an end-capping agent, such as a monobromotriphenylamine derivative, condensed polycyclic monobromo compound, and monobromofluorene derivative (D. Neher, Macromol. Rapid Commun. 2001, 22, 1365-1385).

Specific examples of the end-cap structure are shown below:

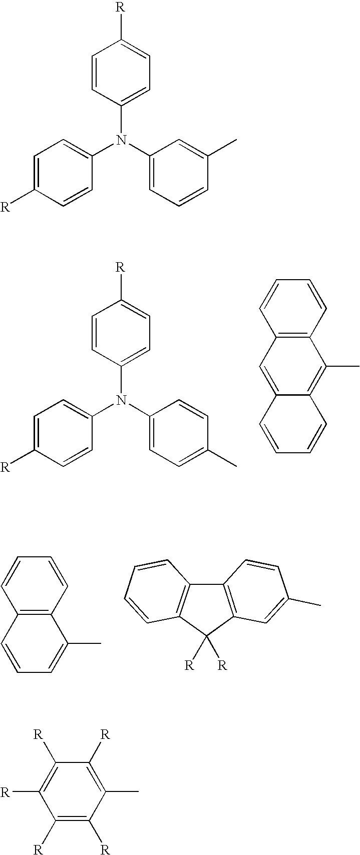

wherein R is the same as R¹ defined above.

While the EL polymer of the present invention can be produced by various polymerization reactions, particularly preferred reactions are C-C coupling reactions (Yamamoto, T.; Hayashida, N.; React. Funct. Polym. 1998, 37, 1, 1), including Yamamoto coupling reaction (Yamamoto, T.; Morita, A.; Miyazaki, Y.; Maruyama, T.; Wakayama, H.; Zhou, Z.-H.; Kanbara, T. Macromolecules 1992, 25, 1214-1223: Yamamoto, T.; Morita, A.; Maruyama, T.; Zhou, Z.-H.; Kanbara, T.; Sanechika, K. Polym. J., 1990, 22, 187-190) and Suzuki coupling reaction (Miyaura, N.; Suzuki, A. Chem. Rev. 1995, 95, 2457-2483). One example is described below in which a fluorene derivative structural unit is used as Ar.

As shown in the reaction scheme A below, a 2,7-dihalogeno (e.g., dibromo) fluorene derivative of the formula (5) (Refer to the production process of Example 1 in Published Japanese Translation No. Hei 11-51535 of PCT Application) is reacted with 2-isopropoxy-4,4,5,5-tetramethyl-1,3,2-dioxabolorane of the formula (6) in the presence of an alkyl lithium (e.g., n-butyl lithium). The reaction is carried out in a solvent (e.g., hexane and THF) at a low temperature (e.g., −78° C.). This gives a fluorene derivative of the formula (7) with boron structures introduced at positions 2 and 7 (N. Miyaura and A. Suzuki, Chem. Rev, 1995, 95, 2457).

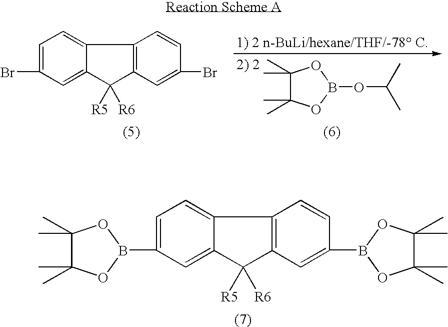

Next, the fluorene derivative of the formula (7) with the boron structures introduced at positions 2 and 7, a 2,2′-dihalogeno (e.g., dibromo) binaphthalene derivative of the formula (8), an optional 2,7-dihalogeno (e.g., dibromo) fluorene derivative of the formula (5), a palladium catalyst (e.g., Pd(PPh₃)₄), and a hydroxide of an alkaline metal or alkaline earth metal (e.g., barium hydroxide) or a carbonate of an alkaline metal or alkaline earth metal (e.g., potassium hydroxide) are reacted in a solvent (e.g., toluene, THF and water) at 0 to 100° C., as shown in the reaction scheme B below. This gives an EL polymer (9) having a structure represented by the formula (1).

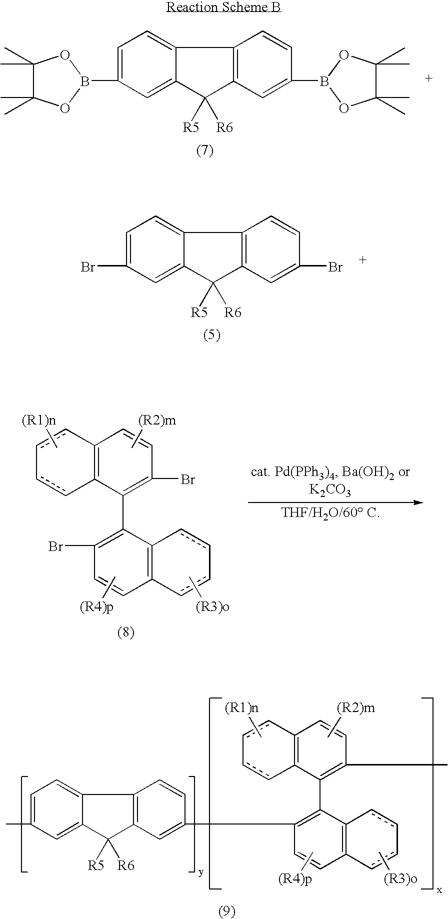

Alternatively, as shown in the reaction scheme C below, a 2,7-dihalogeno (e.g., dibromo) fluorene derivative of the formula (5), a 2,2′-dihalogeno (e.g., dibromo) binaphthalene derivative of the formula (8), and an optional end-capping agent (e.g., 2-bromofluorene derivative) may be reacted in the presence of bis(1,5-cyclooctadiene)nickel (Ni(COD)₂) to give an EL polymer (10) with a structure represented by the formula (1). By adjusting, for example, the amount of the end-capping agent, whether one end or both ends of the backbone of EL polymer are end-capped can be determined.

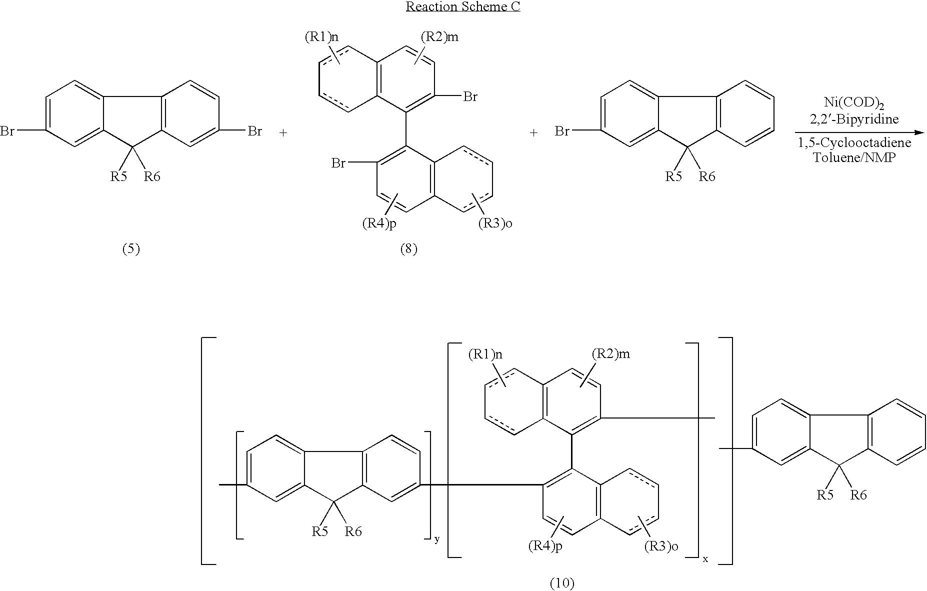

An organic EL device can be constructed by sandwiching a thin film of the EL polymer of the present invention between a pair of electrodes. The EL polymer serves as a luminescent layer. The basic construction of the organic EL device of the present invention may be similar to that of conventional organic EL devices. The organic EL device of the present invention can be used to construct displays, which may have similar construction to conventional organic EL displays.

### EXAMPLES

The present invention will now be described in further detail with reference to examples.

### Reference Example 1

### Synthesis of 2,7-dibromo-9,9-dioctylfluorene

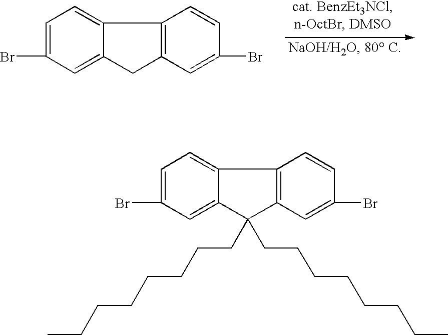

10.0 g (30.9 mmol) of 2,7-dibromofluorene, 19.7 g (102.0 mmol) of 1-bromooctane, 25 ml of dimethyl sulfoxide, 24.9 g (623 mmol) of sodium hydroxide, and 50 ml of water were placed in a 300 ml three-necked flask equipped with a reflux condenser. The mixture was heated to 80° C. Once 2,7-dibromofluorene was completely dissolved, 608 mg (2.66 mmol) of benzyltriethylammonium chloride was added and the mixture was stirred for 20 hours while heated.

Subsequently, the resulting mixture was extracted with hexane, and the extract was dried and hexane was evaporated. Excess 1-bromooctane was then evaporated at high temperature under reduced pressure. The resulting residue was purified by column chromatography (carrier=silica gel, eluent=hexane) to isolate 2,7-dibromo-9,9-dioctylfluorene as a colorless crystal (14.3 g (26.1 mmol), 84.5% yield). The resulting compound was identified by ¹H-NMR and ¹³C-NMR.

¹H-NMR (CDCl₃, δ): 7.58-7.40(m, 6H), 1.90 (t, J=8.1 Hz, 4H), 1.22-1.03 (m, 20H), 0.82 (t, J=6.9 Hz, 6H), 0.58 (brs, 4H) ¹³C-NMR (CDCl₃, δ): 152.5, 139.1, 130.1, 126.2, 121.4, 121.1, 55.7, 40.1, 31.7, 29.6, 29.16, 29.13, 23.6, 22.6, 14.1

### Reference Example 2

### Synthesis of 2,7-dibromo-9,9-di(2-ethylhexyl)fluorene

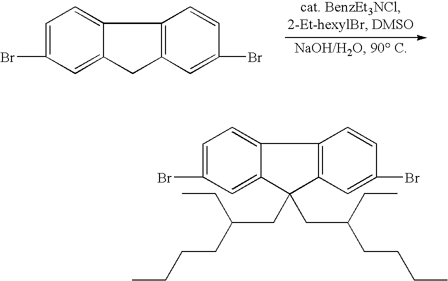

29.3 g (90.4 mmol) of 2,7-dibromofluorene, 75 ml of dimethyl sulfoxide, 60.0 g (311 mmol) of 1-bromo-2-ethylhexane, and 150 ml of 12.5M aqueous sodium hydroxide solution were placed in a 1000 ml egg plant flask and the mixture was stirred. To this mixture, 1.20 g (5.27 mmol) of benzyltriethylammonium chloride were added. At this point, the organic phase was reddish purple. The mixture was mixed for two days at 90° C. and was extracted with diethyl ether. The extract was washed with water and dried.

The dried extract was concentrated. To the concentrate, 50 ml of dimethyl sulfoxide, 29.2 g (151 mmol) of 1-bromo-2-ethylhexane, and 100 ml of 12.5M aqueous sodium hydroxide solution were added and the mixture was stirred. 1.20 g (5.27 mmol) of benzyltriethylammonium chloride were added and the mixture was further stirred for 4 days at 90° C. At this point, the resulting organic phase was reddish purple. The mixture was further stirred for two days at 90° C. and was extracted with diethyl ether. The extract was washed and dried.

The extract was then concentrated and the resulting residue was purified on a column chromatography (carrier:silica gel, eluent:hexane). The eluate was distilled in a Kugelrohr distillation apparatus (80° C.) to remove impurities and thus give 2,7-dibromo-9,9-di(2-ethylhexyl)fluorene as a colorless, clear, and viscous liquid (29.1 g (53.1 mmol), 58.7% yield). The resulting compound was identified by ¹H-NMR and ¹³C-NMR.

¹H-NMR (CDCl₃, δ): 7.70-7.40 (m, 6H), 1.96 (d, J=5.4 Hz, 4H), 1.29 (brs, 2H), 1.02-0.40 (m, 28H) ¹³C-NMR (CDCl₃, δ): 152.2, 139.0, 130.0, 127.4, 127.2, 121.0, 55.4, 44.4, 34.8, 33.6, 28.1, 27.1, 27.0, 14.1, 10.4

### Reference Example 3

### Synthesis of 2,2′-dibromo-1,1′-binaphthyl

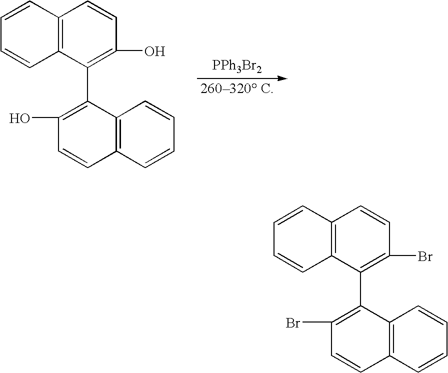

5.67 g (19.8 mmol) of 2,2′-dihydroxy-1,1′-binaphthyl, 25.0 g (59.2 mmol) of triphenylphosphine dibromide, and 20 ml of toluene were placed in a 300 ml egg plant flask. The mixture was thoroughly stirred until uniform and the solvent was removed in a rotary evaporator. The resulting concentrate was stirred at 120° C. for 30 min under a stream of nitrogen gas. Subsequently, the mixture was heated to 260° C., stirred for 1 hour, and further stirred at 320° C. for 30 min to complete the reaction. The mixture was then allowed to cool and was extracted three times with hot toluene. The extracts were concentrated and the concentrate was loaded on a short column (carrier: silica gel, eluent: hexane/toluene (2/1)) to remove impurities. A proper amount of ethanol was then added to the eluate and the resulting precipitate was removed by filtration. This procedure was repeated to obtain a yellow ethanol solution.

The ethanol solution was concentrated and the concentrate was recrystallized with ethanol to give 2,2′-dibromo-1,1′-binaphthyl as a pale yellow powder (1.35 g, 3.28 mmol, 16.5% yield). The resulting compound was identified by GC-MS, ¹H-NMR, and ¹³C-NMR.

1H-NMR (CDCl₃, δ): 7.96-7.74 (m, 8H), 7.55-7.46 (m, 4H), 7.34-7.20 (m, 8H), 7.23-7.07 (m, 4H) ¹³C-NMR (CDCl₃, δ):137.0, 133.2, 132.2, 130.0, 129.7, 128.1, 127.3, 126.2, 125.7, 122.6 GC-MS (m/z, %): 410 (M⁺, 11), 252 (100), 250 (24), 126 (36), 125 (26), 113 (8)

### Reference Example 4

### Synthesis of 2,2′-dibromo-1,1′-biphenyl

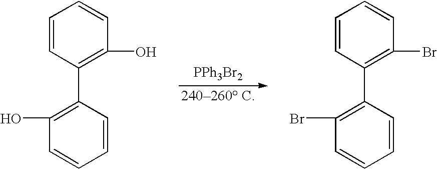

Under a stream of nitrogen gas, 4.00 g (21.5 mmol) of 2,2′-biphenol and 20.4 g (48.3 mmol) of triphenylphosphine dibromide were placed in a 200 ml egg plant flask, and the mixture was stirred at 240-260° C. for 1 hour while heated. Subsequently, the mixture was heated from 260° C. to 270° C. and was stirred for 1 hour while heated and another 30 min at 310-320° C.

Once the reaction was completed, the mixture was extracted with toluene and the solvent was evaporated. The resulting residue was purified by a column chromatography (carrier: silica gel, eluent: toluene) to isolate 2,2′-dibromo-1,1′-biphenyl as a colorless crystal (4.12 g, 13.2 mmol, 61.4% yield). The resulting compound was identified by GC-MS ¹H-NMR, and ¹³C-NMR.

¹H-NMR (CDCl₃, δ): 7.67 (d, J=9.0 Hz, 2H), 7.40 (t, J=9.0 Hz, 2H), 7.30-7.23 (m, 4H) ¹³C-NMR (CDCl₃, δ): 141.9, 132.5, 130.8, 129.3, 127.0, 123.4 GC-MS (m/z, %): 312 (M⁺+2, 52), 310 (M⁺, 27), 233 (59), 231 (59), 152 (100), 141 (29), 76(58), 75(23), 63 (18)

### Reference Example 5

### Synthesis of 2,2′-bis(trifluoromethyl)-4,4′-dibromobiphenyl[TFMB] (Sandmyer Reaction)

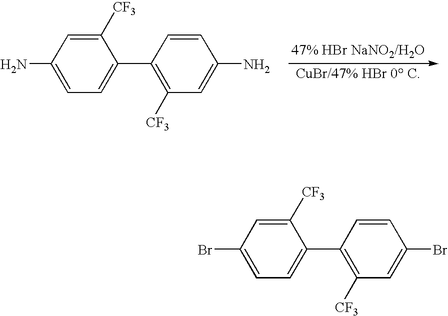

3.19 g (9.96 mmol) of 2,2′-bis(trifluoromethyl)-4,4′-diaminobiphenyl and 3 ml of water were placed in a 200 ml four-necked flask, followed by addition of 3.9 g (22.7 mmol) of 47% aqueous hydrogen bromide solution at room temperature. Once the materials were completely dissolved, additional 6.0 g (34.9 mmol) of 47% aqueous hydrogen bromide solution and then a block of ice were added. Subsequently, 14 ml aqueous solution of 1.38 g (20.0 mmol) sodium nitrite was slowly added at 0° C. or below. After 5 min, the presence of nitrous acid was confirmed by a test paper. To this reaction mixture, a mixture of copper (I) bromide/47% aqueous hydrogen bromide solution (3.44 g (24. mmol)/22.1 g (128 mmol)) was added and the resulting mixture was allowed to gradually warm to room temperature. This was followed by stirring overnight and addition of a 10% aqueous sodium hydroxide solution to terminate the reaction.

Subsequently, the mixture was extracted with diethyl ether and THF. The extract was sequentially washed with 1N hydrochloric acid, a saturated aqueous solution of sodium hydrogencarbonate and a saturated aqueous solution of sodium chloride, and was dried over anhydrous magnesium sulfate. The dried extract was concentrated and the concentrate was purified by column chromatography (carrier: silica gel, eluent: hexane) to give 2,2′-bis(trifluoromethyl)-4,4′-dibromobiphenyl as white crystal (2.42 g, 5.40 mmol, 54.2% yield). The resulting compound was identified by GC-MS, ¹H-NMR, and ¹³C-NMR.

H-NMR (CDCl₃, δ): 7.90 (s, 2H), 7.71 (d, J=8.1 Hz, 2H), 7.20 (d, J=8.1 Hz, 2H) ¹³C-NMR (CDCl₃, δ): 135.0, 133.7, 132.8, 130.4 (q, ²J (¹³C-¹⁹ F)=31 Hz), 129.3, 122.7 (q, ¹J (¹³C-¹⁹F)=272 Hz, CF₃), 122.5 GC-MS (m/z, %): 448 (M⁺+2, 74), 446 (M⁺, 100), 348 (10), 300 (36), 288 (52), 269 (27), 268 (13), 219 (80), 199 (19), 169 (11), 99 (19), 75 (18), 69 (18)

### Reference Example 6

### Synthesis of 9,9-dioctylfluorene with Boron Structures Introduced at Positions 2 and 7

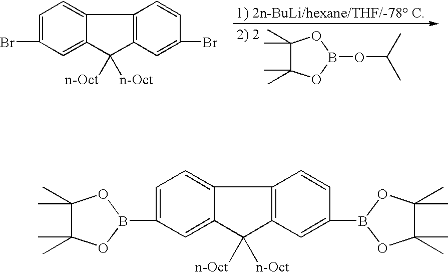

Under a stream of nitrogen gas, 8.20 g (15.0 mmol) of 2,7-dibromo-9,9-dioctylfluorene and 100 ml of tetrahydrofuran were placed in a 200 ml three-necked flask equipped with a 100 ml dropping funnel and a reflux condenser. After the reaction vessel was chilled to −78° C. in a methanol/dry ice bath, 28.0 ml (44.2 mmol) of n-butyllithium (1.58M hexane solution) were added dropwise from the dropping funnel. While kept at −78° C., the mixture was stirred for about 1 hour. Subsequently, 9.0 ml (44.0 mmol) of 2-isopropoxy-4,4,5,5-tetramethyl-1,3,2-dioxabolorane were added to the mixture and the reaction vessel was taken out of the methanol/dry ice bath. The mixture was then stirred for about 11 hours.

The resulting reaction mixture was extracted with diethyl ether and the extract was dried. Diethyl ether was evaporated and the resulting residue colorless crystal was purified by washing with methanol to give the fluorene compound of the formula (7) (R¹=n-octyl group) (7.94 g, 12.4 mmol, 83.2% yield). The resulting compound was identified by ¹H-NMR and ¹³C-NMR.

### Reference Example 7

### Synthesis of Triphenylamine Derivative as End-Capping Agent

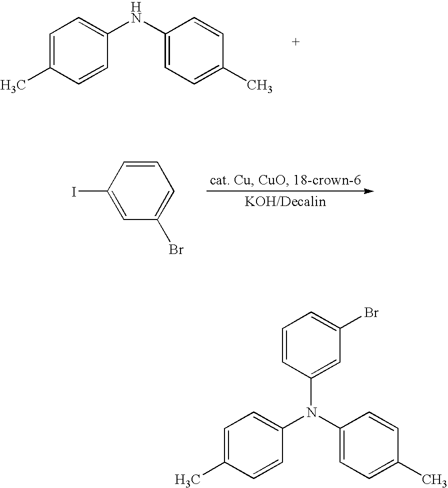

A 200 ml three-necked flask equipped with a reflux tube was completely vacuum dried. Under a nitrogen atmosphere, 20.1 g (102 mmol) of di(p-tolyl)amine, 29.2 g (103 mmol) of 3-bromo-1-iodobenzene, 0.8 g of copper powder, 0.8 g of copper oxide (II), 7.4 g of potassium hydroxide, 130 g of decalin, and 0.4 g of 18-crown-6 were placed in the vessel and the mixture was thoroughly mixed. The mixture was then stirred for 3 days at 150° C. under a nitrogen atmosphere. Subsequently, the mixture was extracted, was purified by column chromatography (carrier:silica gel, eluate: hexane), and was distilled in a Kugelrohr distillation apparatus to remove impurities and thus give a triphenylamine derivative as white crystal (11.72 g, 33.2 mmol, 32.7% yield). The resulting compound was identified by GC-MS, ¹H-NMR, and ¹³C-NMR.

¹H-NMR (CDCl₃, δ): 7.11-6.84 (m, 12H), 2.31 (s, 6H) ¹³C-NMR (CDCl₃, δ): 149.6, 144.5, 133.1, 130.0, 129.9, 124.9, 124.2, 123.8, 122.6, 120.1, 20.9 GC-MS (m/z, %): 353 (M⁺+2, 52), 351 (M⁺, 100), 272 (6), 257 (10), 180 (10), 155 (7), 136 (10), 127 (6), 91 (7), 65 (6)

### Reference Example 8

### Synthesis of 1,5-dibromonaphthalene

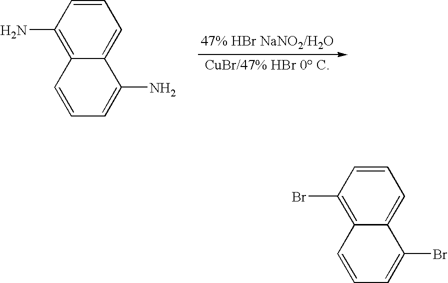

3.21 g (20.3 mmol) of 1,5-diaminonaphthalene and 6 ml of water were placed in a 500 ml three-necked flask and 19.0 g (110 mmol) of 47% aqueous hydrogen bromide solution was added at room temperature. Following addition of an ice block, 8 ml aqueous solution of 2.76 g (40.0 mmol) sodium nitrite was slowly added at 0° C. or below. After 5 min, the presence of nitrous acid was confirmed by a test paper. To the reaction mixture, a mixture of copper (I) bromide/47% aqueous hydrogen bromide solution (6.91 g (48.2 mmol)/44.0 g (256 mmol)) was added, and the resulting mixture was allowed to gradually warm to room temperature, followed by stirring overnight and addition of a 10% aqueous sodium hydroxide solution to terminate the reaction. Subsequently, the mixture was extracted with diethyl ether and THF. The extract was sequentially washed with 1N hydrochloric acid, a saturated aqueous solution of sodium hydrogencarbonate and a saturated aqueous solution of sodium chloride, and was dried over anhydrous magnesium sulfate. The extract was concentrated and the concentrate was purified by column chromatography (carrier:silica gel, eluent:hexane) to give 140 mg white crystal (2.4% yield, 0.490 mmol). The resulting compound was identified by GC-MS, ¹H-NMR, and ¹³C-NMR (Sandmyer reaction).

¹H-NMR (CDCl₃, δ): 8.25 (d, J=7.8 Hz, 2H), 7.84 (d, J=7.8 Hz, 2H), 7.43 (t, J=7.8 Hz, 2H) ¹³C-NMR (CDCl₃, δ): 132.9, 130.8, 127.3, 127.2, 122.9 GC-MS (m/z, %): 286 (M⁺², 100), 284 (M⁺, 92), 207 (39), 205 (40), 126 (100, 74 (27), 63 (61)

### Reference Example 9

### Synthesis of 2,5-bis(4-bromophenyl)-1,3,4-oxadiazole

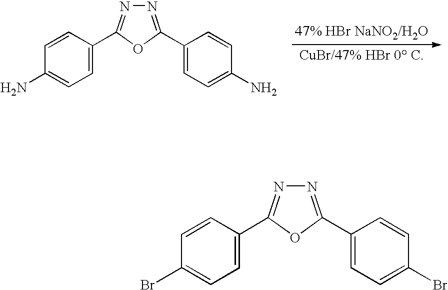

2.11 g (8.36 mmol) of 2,5-bis(4-diaminophenyl)-1,3,4-oxadiazole and 2.6 ml of water were placed in a 200 ml four-necked flask and 3.14 g (18.2 mmol) of 47% aqueous hydrogen bromide solution was added at room temperature. Once the materials were completely dissolved, additional 4.58 g (26.6 mmol) of 47% aqueous hydrogen bromide solution and then a block of ice were added. Subsequently, 3 ml aqueous solution of 1.10 g (15.9 mmol) sodium nitrite was slowly added at 0° C. or below. After 5 min, the presence of nitrous acid was confirmed by a test paper. To the reaction mixture, a mixture of copper (I) bromide/47% aqueous hydrogen bromide solution (2.70 g (18.8 mmol)/17.5 g (102 mmol)) was added, and the resulting mixture was allowed to gradually warm to room temperature, followed by stirring overnight and addition of a 10% aqueous sodium hydroxide solution to terminate the reaction. Subsequently, the mixture was extracted with diethyl ether and THF. The extract was sequentially washed with 1N hydrochloric acid, a saturated aqueous solution of sodium hydrogencarbonate and a saturated aqueous solution of sodium chloride, and was dried over anhydrous magnesium sulfate. The extract was concentrated and the concentrate was washed and recrystallized with ethanol to give 1.59 g pale brown crystal (4.18 mmol, 50% yield). The resulting compound was identified by GC-MS, ¹H-NMR, and ¹³C-NMR.

¹H-NMR (CDCl₃, δ): 8.05 (d, J=6.0 Hz, 4H), 7.60 (d, J=6.0 Hz, 4H) ¹³C-NMR (CDCl₃, δ): 163.9, 132.4, 128.2, 126.5, 122.5 GC-MS (m/z, %): 380 (M⁺+2, 75), 378 (M⁺, 40), 245 (34), 253 (34), 183 (100), 157 (39), 155 (39), 102 (13), 88 (18), 76 (35), 75 (31), 50 (18)

### Example 1

### Synthesis of 9,9-dioctylfluorene Polymer with 20 mol % Introduced 2,2′-dibromo-1,1′-binaphthyl [PDOF80-BiNp20]

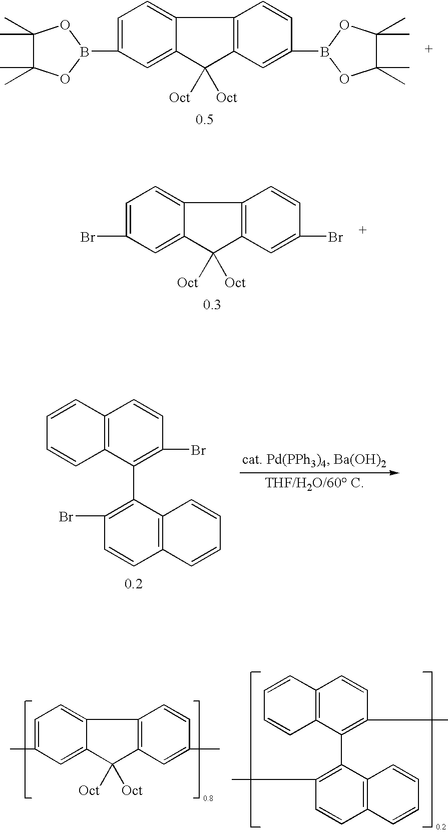

Under a stream of nitrogen gas, 0.412 g (1.00 mmol) of 2,2′-dibromo-1,1′-binaphthyl, 0.822 g (1.50 mmol) of 2,7-dibromo-9,9-dioctylfluorene, 1.59 g (2.50 mmol) of 9,9-dioctylfluorene with boron structures introduced at positions 2 and 7, 3.15 g (9.99 mmol) of barium hydroxide octahydrate, 10 ml of THF, and 7 ml of distilled water were placed in a 100 ml three-necked flask equipped with a reflux condenser and the mixture was heated to 60° C. Once the solutes were completely dissolved, 50 mg of tetrakis(triphenylphosphine)palladium were added and the mixture was stirred for about 48 hours while heated.

Subsequently, toluene was added to the resulting mixture, and as much of the solvent as possible was evaporated to obtain a viscous material. This material was washed sequentially with 1N hydrochloric acid, 1N aqueous sodium hydroxide solution, and distilled water to remove barium hydroxide. The resultant material was dissolved in a small amount of THF and was re-precipitated twice in methanol. The precipitate was purified by soxhlet extraction (acetone) for about 48 hours to give an EL polymer (0.81 g) composed of 9,9-dioctylfluorene structural units and 1,1′-binaphthyl structural units.

A gel permeation chromatography of the polymer (THF solvent, compared with polystyrene of known molecular weight) revealed that the polymer had a weight average molecular weight of 35351 and a number average molecular weight of 14053. The concentration of inorganic metal elements present in the polymer proved to be less than the detection limit of the energy dispersive x-ray analysis (EDX) (0.1%).

### Comparative Example 1

### Synthesis of 9,9-dioctylfluorene Polymer [PDOF]

Under a stream of nitrogen gas, 1.71 g (3.12 mmol) of 2,7-dibromo-9,9-dioctylfluorene, 2.02 g (3.14 mmol) of 9,9-dioctylfluorene with boron structures introduced at positions 2 and 7, 2.2 g of potassium carbonate, 16 ml of THF, and 8 ml of distilled water were placed in a 100 ml three-necked flask equipped with a reflux condenser and the mixture was heated to 60° C. Once the solutes were completely dissolved, 50 mg of tetrakis(triphenylphosphine)palladium were added and the mixture was stirred for about 48 hours while heated.

Subsequently, toluene was added to the resulting mixture, and as much of the solvent as possible was evaporated to obtain a viscous material. This material was washed sequentially with 1N hydrochloric acid, 1N aqueous sodium hydroxide solution, and distilled water to remove potassium carbonate. The resultant material was dissolved in a small amount of THF and was re precipitated twice in methanol. The precipitate was purified by soxhlet extraction (acetone) for about 48 hours to give an EL polymer (1.84 g) composed solely of 9,9-dioctylfluorene structural units.

A gel permeation chromatography of the polymer (THF solvent, compared with polystyrene of known molecular weight) revealed that the polymer had a weight average molecular weight of 37097 and a number average molecular weight of 10993. The concentration of inorganic metal elements present in the polymer proved to be less than the detection limit of the energy dispersive x-ray analysis (EDX) (0.1%).

### Comparative Example 2

### Synthesis of 9,9-dioctylfluorene Polymer with 20 mol % Introduced 2,2′-dibromo-1,1′-biphenyl [PDOF80-BiPh20]

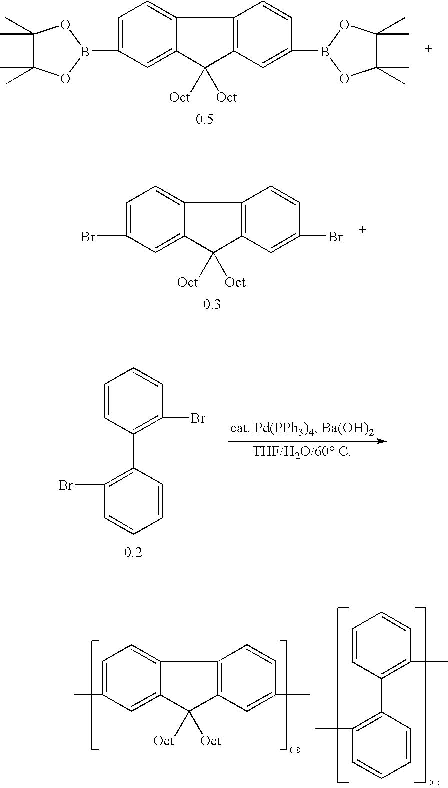

Under a stream of nitrogen gas, 0.187 g (0.600 mmol) of 2,2′-dibromobiphenyl, 0.493 g (0.899 mmol) of 2,7-dibromo-9,9-dioctylfluorene, 0.964 g (1.5 mmol) of 9,9-dioctylfluorene with boron structures introduced at positions 2 and 7, 3.15 g (9.99 mmol) of barium hydroxide octahydrate, 10 ml of THF, and 7 ml of distilled water were placed in a 100 ml three-necked flask equipped with a reflux condenser and the mixture was heated to 60° C. Once the solutes were completely dissolved, 50 mg of tetrakis(triphenylphosphine)palladium were added and the mixture was stirred for about 48 hours while heated. Toluene was added to the mixture and as much of the solvent as possible was evaporated to obtain a viscous material. This material was washed sequentially with 1N hydrochloric acid, 1N aqueous sodium hydroxide solution, and distilled water to remove barium hydroxide.

The resultant viscous material was dissolved in a small amount of THF and was re-precipitated twice in methanol. The precipitate was purified by soxhlet extraction (acetone) for about 48 hours to give an EL polymer (0.60 g) composed of 9,9-dioctylfluorene structural units and 1,1′-diphenyl structural units.

A gel permeation chromatography of the polymer (THF solvent, compared with polystyrene of known molecular weight) revealed that the polymer had a weight average molecular weight of 29138 and a number average molecular weight of 13228. The concentration of inorganic metal elements present in the polymer proved to be less than the detection limit of the energy dispersive x-ray analysis (EDX) (0.1%).

### Example 2

### Synthesis of 9,9-dioctylfluorene Polymer with 20 mol % Introduced 2,2′-dibromo-1,1′-binaphthyl and End-Capped with 4 mol % Triphenylamine (TPA)

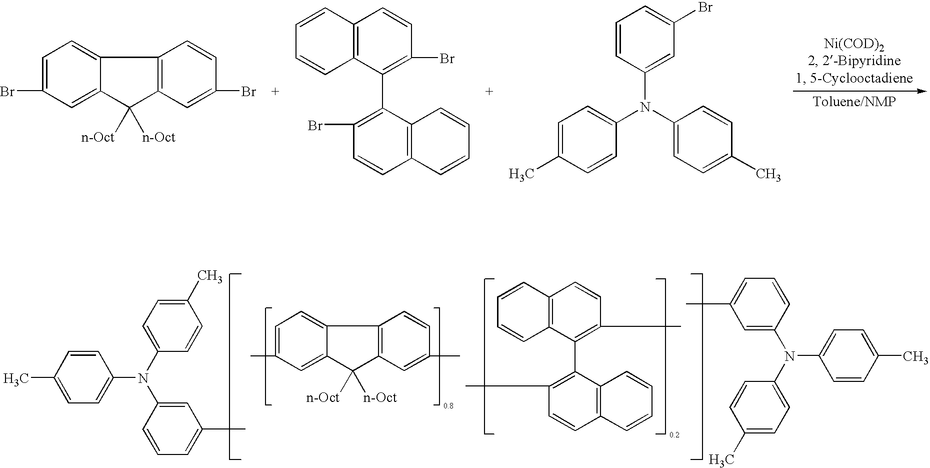

2.00 mg (7.27 mmol) of bis(1,5-cyclooctadiene)nickel(0) and 1.22 g (7.81 mmol) of 2,2′-bipyridine were placed in a vacuum-dried 100 ml three-necked flask (vessel A). The vessel was evacuated for 10 min and dry nitrogen was introduced to atmospheric pressure. 20 ml of toluene and 8 ml of N-methylpyrrolidone were then added and the mixture was stirred at 80° C. for 30 min.

Meanwhile, 1.39 g (2.58 mmol) of 2,7-dibromo-9,9-dioctylfluorene, 0.227 mg (0.67 mmol) of 2,2′-dibromo-1,1′-binaphthyl, and 47 mg (0.13 mmol) of 3-bromo-4′,4″-dimethyltriphenylamine (end-capping agent) were placed in a separate vacuum-dried flask (vessel B) under a dry nitrogen atmosphere. 12 ml of toluene were further added to dissolve the compounds. While care was taken to avoid contact with the air, the solution in the vessel B was transferred to the vessel A. Following stirring for 5 min, 440 mg (4.07 mmol) of 1,5-cyclooctadiene was added and the reaction were allowed to proceed at 80° C. for 3 days.

Subsequently, as much of the solvent as possible was removed to obtain a viscous material. This viscous material was washed sequentially with 1N hydrochloric acid, 1N aqueous sodium hydroxide solution and distilled water. The washed material was then dissolved in a small amount of THF and was re-precipitated twice in methanol to give an EL polymer (0.686 g) composed of 9,9-dioctylfluorene structural units, 1,1′-binaphthyl structural units and triphenylamine end-capping agent.

A gel permeation chromatography of the polymer (THF solvent, compared with polystyrene of known molecular weight) revealed that the polymer had a weight average molecular weight of 11980 and a number average molecular weight of 6454. The results of ¹H-NMR indicated that the amount of the terminal TPA was 4% of the charged amount. The concentration of inorganic metal elements present in the polymer proved to be less than the detection limit of the energy dispersive x-ray analysis (EDX) (0.1%).

### Example 3

### Synthesis of 9,9-di(2-ethylhexyl)fluorene Polymer with 20 mol % Introduced 2,2′-dibromo-1,1′-binaphthyl and End-Capped with 4 mol % Triphenylamine (TPA)

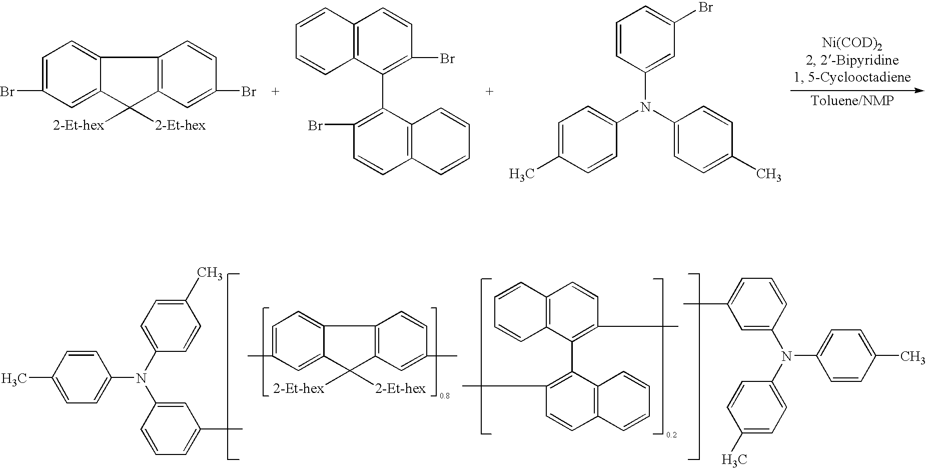

1.00 g (3.64 mmol) of bis(1,5-cyclooctadiene)nickel (0) and 610 mg (3.91 mmol) of 2,2′-bipyridine were placed in a vacuum-dried 100 ml three-necked flask (vessel A). The vessel was evacuated for 10 min and dry nitrogen was introduced to atmospheric pressure. 10 ml of toluene and 4 ml of N-methylpyrrolidone were then added and the mixture was stirred at 80° C. for 30 min.

Meanwhile, 694 mg (1.27 mmol) of 2,7-dibromo-9,9-diethylhexylfluorene, 137 mg (0.33 mmol) of 2,2′-dibromo-1,1′-binaphthyl, and 24 mg (0.07 mmol) of triphenylamine (end-capping agent), were placed in a separate vacuum-dried flask (vessel B) under a dry nitrogen atmosphere. 6 ml of toluene were further added to dissolve the compounds. While care was taken to avoid contact with the air, the solution in the vessel B was transferred to the vessel A. Following stirring for 5 min, 220 mg (2.03 mmol) of 1,5-cyclooctadiene were added and the reaction was allowed to proceed at 80° C. for 3 days. Subsequently, as much of the solvent as possible was removed to obtain a viscous material.

This viscous material was washed sequentially with 1N hydrochloric acid, 1N aqueous sodium hydroxide solution, and distilled water. The washed material was then dissolved in a small amount of THF and was re-precipitated twice in methanol to give an EL polymer (0.310 g) composed of 9,9-diethylhexylfluorene structural units, 1,1′-dinaphthyl structural units, and triphenylamine end-capping agent.

A gel permeation chromatography of the polymer (THF solvent, compared with polystyrene of known molecular weight) revealed that the polymer had a weight average molecular weight of 10104 and a number average molecular weight of 6585. The results of ¹H-NMR indicated that the amount of the terminal TPA was 4% of the charged amount. The concentration of inorganic metal elements present in the polymer proved to be less than the detection limit of the energy dispersive x-ray analysis (EDX) (0.1%).

### Example 4

### Synthesis of 2,2′-bis(trifluoromethyl)-4,4′-dibromobiphenyl (TFMB) polymer with 20 mol % introduced 2,2′-dibromo-1,1′-binaphthyl

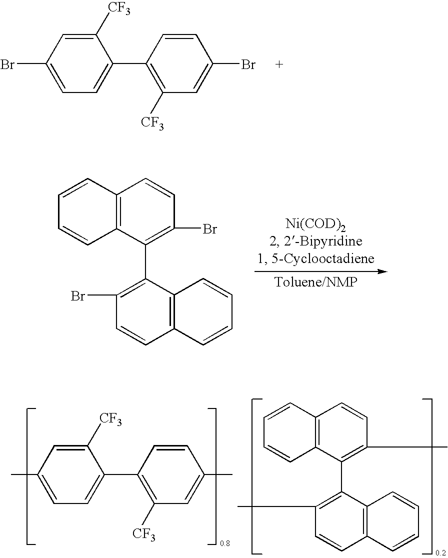

1.00 mg (3.64 mmol) of bis(1,5-cyclooctadiene)nickel(0) and 610 mg (3.91 mmol) of 2,2′-bipyridine were placed in a vacuum-dried 100 ml three-necked flask (vessel A). The vessel was evacuated for 10 min and dry nitrogen was introduced to atmospheric pressure. 10 ml of toluene and 4 ml of N-methylpyrrolidone were then added and the mixture was stirred at 80° C. for 30 min.

Meanwhile, 606 mg (1.35 mmol) of 2,2′-bis(trifluoromethyl)-4,4′-dibromobiphenyl and 139 mg (0.34 mmol) of 2,2′-dibromo-1,1′-binaphthyl were placed in a separate vacuum-dried flask (vessel B) under a dry nitrogen atmosphere. 6 ml of toluene were further added to dissolve the compounds. While care was taken to avoid contact with the air, the solution in the vessel B was transferred to the vessel A. Following stirring for 5 min, 210 mg (1.94 mmol) of 1,5-cyclooctadiene were added and the reaction was allowed to proceed at 80° C. for 3 days. Subsequently, as much of the solvent as possible was removed to obtain a viscous material.

This viscous material was washed sequentially with 1N hydrochloric acid, 1N aqueous sodium hydroxide solution, and distilled water. The washed material was then dissolved in a small amount of THF and was re-precipitated twice in methanol to give an EL polymer (0.203 g) composed of biphenyl structural units, 1,1′-binaphthyl structural units and triphenylamine end-capping agent.

A gel permeation chromatography of the polymer (THF solvent, compared with polystyrene of known molecular weight) revealed that the polymer had a weight average molecular weight of 46235 and a number average molecular weight of 18920. The concentration of inorganic metal elements present in the polymer proved to be less than the detection limit of the energy dispersive x-ray analysis (EDX) (0.1%).

### Example 5

### Synthesis of Copolymer Composed of 20 mol % 2,2′-dibromo-1,1′-binaphthyl, 70 mol % 2,7-dibromo-9,9-diethylhexylfluorene, and 10 mol % 2,2′-bis(trifluoromethyl)-4,4′-dibromobiphenyl [BiNp20-EthylHexFL70-TFMB10]

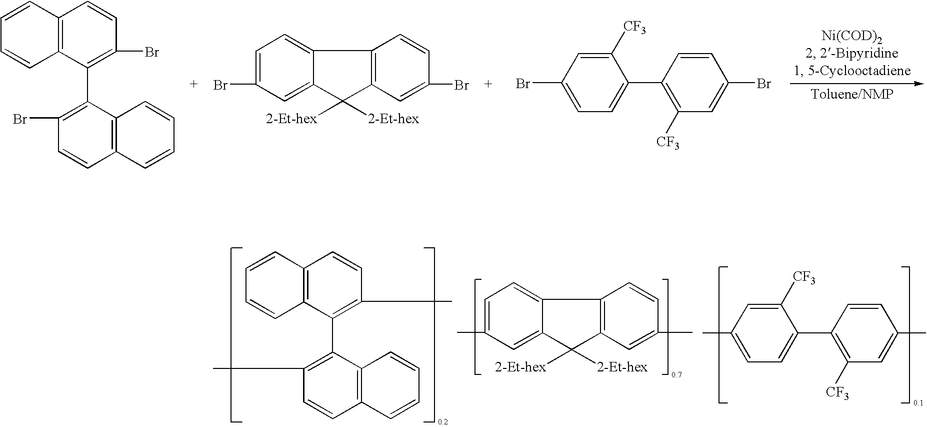

1.00 g (3.64 mmol) of bis(1,5-cyclooctadiene)nickel (0) and 613 mg (3.92 mmol) of 2,2′-bipyridine were placed in a vacuum-dried 100 ml three-necked flask. The vessel was evacuated for 10 min and dry nitrogen was introduced to atmospheric pressure. 10 ml of toluene and 4 ml of N-methylpyrrolidone (NMP) were then added and the mixture was stirred at 80° C. for 30 min (vessel A).

Meanwhile, 74 mg (0.17 mmol) of 2,2′-bis(trifluoromethyl)-4,4′-dibromobiphenyl, 139 mg (0.34 mmol) of 2,2′-dibromo-1,1′-binaphthyl, and 644 mg (1.17 mmol) of 2,7-dibromo-9,9-diethylhexylfluorene were placed in a separate vacuum-dried vessel B under a dry nitrogen atmosphere. 6 ml of toluene were further added to dissolve the compounds. While care was taken to avoid contact with the air, the solution in the vessel B was transferred to the vessel A. Following stirring for 5 min, 215 mg (1.99 mmol) of 1,5-cyclooctadiene were added and the reaction was allowed to proceed at 80° C. for 3 days. Subsequently, as much of the solvent as possible was removed to obtain a viscous material.

This material was washed sequentially with 1N hydrochloric acid, 1N aqueous sodium hydroxide solution, and distilled water. The washed material was then dissolved in a small amount of THF and was re-precipitated twice in methanol to give 335 mg of the desired product. The results of GPC (eluant: THF, compared with polystyrene of known molecular weight) indicated that the polymer had a weight average molecular weight (Mw) of 32420 and a number average molecular weight (Mn) of 14807. The concentration of inorganic metal elements present in the polymer proved to be less than the detection limit of the energy dispersive x-ray analysis (EDX) (0.1%).

### Example 6

### Synthesis of Copolymer Composed of 20 mol % 2,2′-dibromo-1,1′-binaphthyl, 70 mol % 2,7-dibromo-9,9-diethylhexylfluorene, and 10 mol % 1,5-dibromonaphthalene[BiNp20-EthylHexFL70-DBN10]

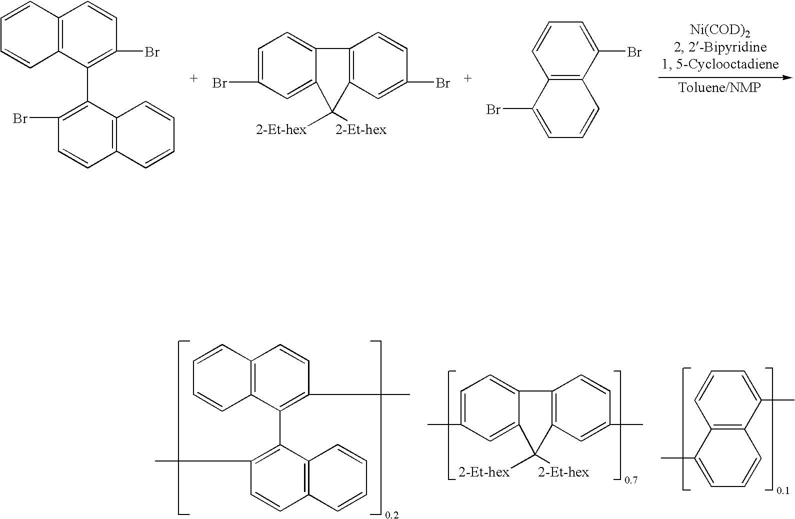

1.00 g (3.64 mmol) of bis(1,5-cyclooctadiene)nickel(0) and 617 mg (3.95 mmol) of 2,2′-bipyridine were placed in a vacuum-dried 100 ml three-necked flask. The vessel was evacuated for 10 min and dry nitrogen was introduced to atmospheric pressure. 10 ml of toluene and 4 ml of NMP were then added and the mixture was stirred at 80° C. for 30 min (vessel A).

Meanwhile, 48 mg (0.17 mmol) of 1,5-dibromonaphthalene, 139 mg (0.34 mmol) of 2,2′-dibromo-1,1′-binaphthyl, and 645 mg (1.18 mmol) of 2,7-dibromo-9,9-diethylhexylfluorene were placed in a separate vacuum-dried vessel B under a dry nitrogen atmosphere. 6 ml of toluene were further added to dissolve the compounds. While care was taken to avoid contact with the air, the solution in the vessel B was transferred to the vessel A. Following stirring for 5 min, 218 mg (2.01 mmol) of 1,5-cyclooctadiene were added and the reaction was allowed to proceed at 80° C. for 3 days. Subsequently, as much of the solvent as possible was removed to obtain a viscous material.

This material was washed sequentially with 1N hydrochloric acid, 1N aqueous sodium hydroxide solution, and distilled water. The washed material was then dissolved in a small amount of THF and was re-precipitated twice in methanol to give 330 mg of the desired product. The results of GPC (eluant: THF, compared with polystyrene of known molecular weight) indicated that the polymer had a weight average molecular weight (Mw) of 22876 and a number average molecular weight (Mn) of 10624. The concentration of inorganic metal elements present in the polymer proved to be less than the detection limit of the energy dispersive x-ray analysis (EDX) (0.1%).

### Example 7

### Synthesis of Copolymer Composed of 20 mol % 2,2′-dibromo-1,1′-binaphthyl, 70 mol % 2,7-dibromo-9,9-diethylhexylfluorene, and 10 mol % 9,10-dibromoanthracene [BiNp20-EthylHexFL70-An10]

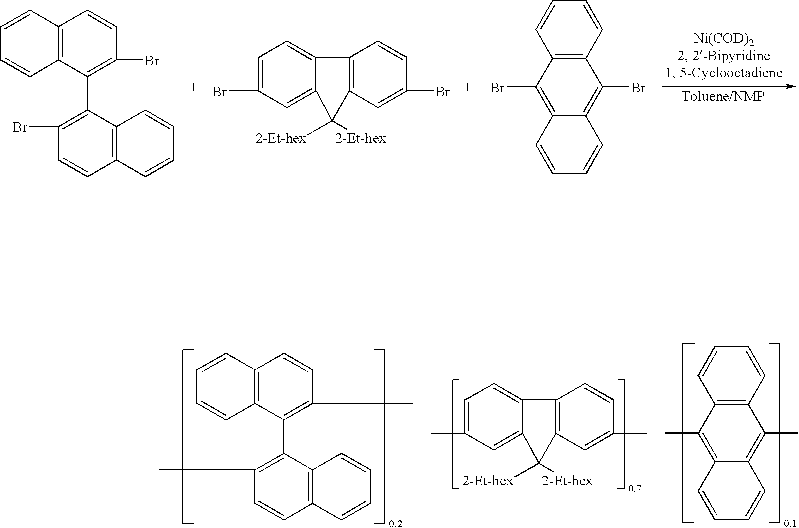

1.00 g (3.64 mmol) of bis(1,5-cyclooctadiene)nickel(0) and 610 mg (3.91 mmol) of 2,2′-bipyridine were placed in a vacuum-dried 100 ml three-necked flask. The vessel was evacuated for 10 min and dry nitrogen was introduced to atmospheric pressure. 10 ml of toluene and 4 ml of NMP were then added and the mixture was stirred at 80° C. for 30 min (vessel A).

Meanwhile, 56 mg (0.17 mmol) of 9,10-dibromoanthracene, 139 mg (0.34 mmol) of 2,2′-dibromo-1,1′-binaphthyl, and 645 mg (1.18 mmol) 2,7-dibromo-9,9-diethylhexylfluorene were placed in a separate vacuum-dried vessel B under a dry nitrogen atmosphere. 6 ml of toluene were further added to dissolve the compounds. While care was taken to avoid contact with the air, the solution in the vessel B was transferred to the vessel A. Following stirring for 5 min, 220 mg (2.03 mmol) of 1,5-cyclooctadiene were added and the reaction was allowed to proceed at 80° C. for 3 days. Subsequently, as much of the solvent as possible was removed to obtain a viscous material.

This material was washed sequentially with 1N hydrochloric acid, 1N aqueous sodium hydroxide solution, and distilled water. The washed material was then dissolved in a small amount of THF and was re-precipitated twice in methanol to give 370 mg of the desired product. The results of GPC (eluant: THF, compared with polystyrene of known molecular weight) indicated that the polymer had a weight average molecular weight (Mw) of 22822 and a number average molecular weight (Mn) of 10652. The concentration of inorganic metal elements present in the polymer proved to be less than the detection limit of the energy dispersive x-ray analysis (EDX) (0.1%).

### Example 8

### Synthesis of Copolymer Composed of 20 mol % 2,2′-dibromo-1,1′-binaphthyl, 70 mol % 2,7-dibromo-9,9-diethylhexylfluorene, and 10 mol % 3,6-dibromo-N-octylcarbazole [BiNp20-EthylHexFL70-Carb10]

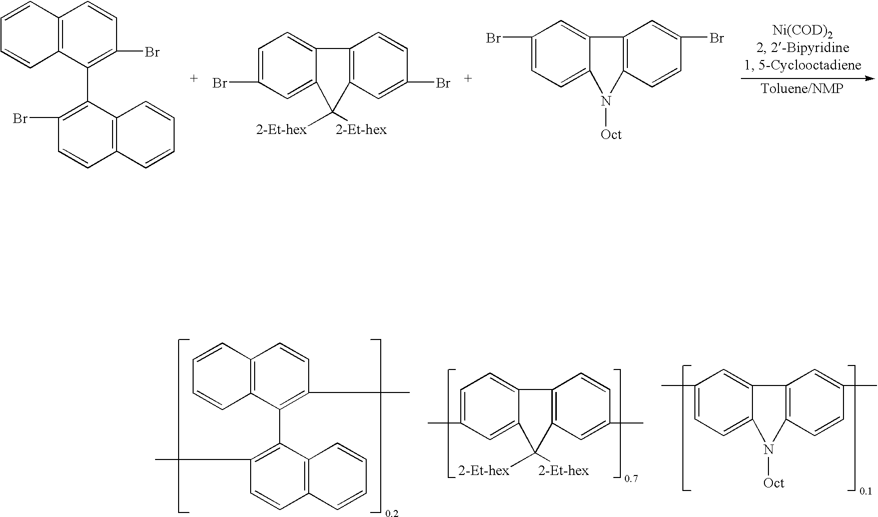

1.00 g (3.64 mmol) of bis(1,5-cyclooctadiene)nickel(0) and 610 mg (3.91 mmol) of 2,2′-bipyridine were placed in a vacuum-dried 100 ml three-necked flask. The vessel was evacuated for 10 min and dry nitrogen was introduced to atmospheric pressure. 10 ml of toluene and 4 ml of NMP were then added and the mixture was stirred at 80° C. for 30 min (vessel A).

Meanwhile, 73 mg (0.17 mmol) of 3,6-dibromo-N-octylcarbazole, 139 mg (0.34 mmol) of 2,2′-dibromo-1,1′-binaphthyl, and 645 mg (1.18 mmol) of 2,7-dibromo-9,9-diethylhexylfluorene were placed in a separate vacuum-dried vessel B under a dry nitrogen atmosphere. 6 ml of toluene were further added to dissolve the compounds. While care was taken to avoid contact with the air, the solution in the vessel B was transferred to the vessel A. Following stirring for 5 min, 220 mg (2.03 mmol) of 1,5-cyclooctadiene was added and the reaction was allowed to proceed at 80° C. for 3 days. Subsequently, as much of the solvent as possible was removed to obtain a viscous material.

This material was washed sequentially with 1N hydrochloric acid, 1N aqueous sodium hydroxide solution and distilled water. The washed material was then dissolved in a small amount of THF and was re-precipitated twice in methanol to give 350 mg of the desired product. The results of GPC (eluant: THF, compared with polystyrene of known molecular weight) indicated that the polymer had a weight average molecular weight (Mw) of 19988 and a number average molecular weight (Mn) of 9764. The concentration of inorganic metal elements present in the polymer proved to be less than the detection limit of the energy dispersive x-ray analysis (EDX) (0.1%).

### Example 9

### Synthesis of Copolymer Composed of 20 mol % 2,2′-dibromo-1,1′-binaphthyl, 70 mol % 2,7-dibromo-9,9-diethylhexylfluorene, and 10 mol % 2,5-bis(4-bromophenyl)-1,3,4-oxadiazole [BiNp20-EthylHexFL70-Diazo10]

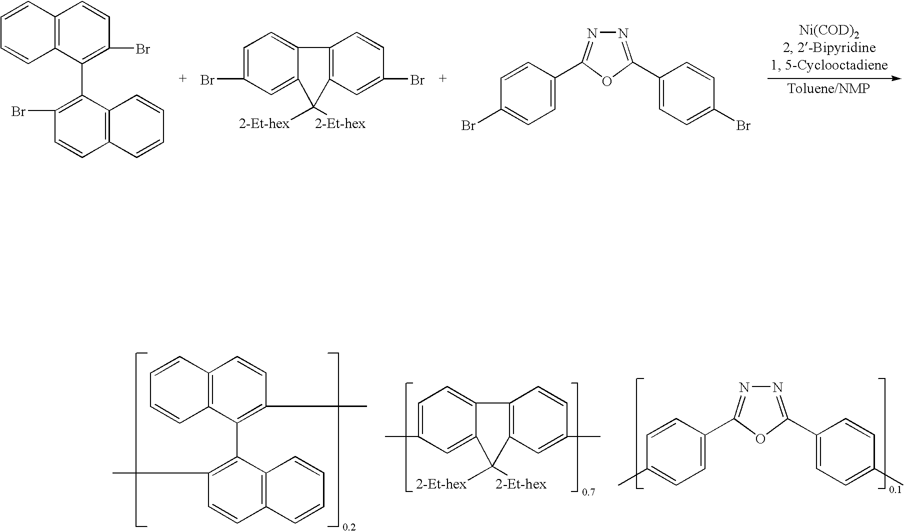

1.00 g (3.64 mmol) of bis(1,5-cyclooctadiene)nickel(0) and 613 mg (3.92 mmol) of 2,2′-bipyridine were placed in a vacuum-dried 100 ml three-necked flask. The vessel was evacuated for 10 min and dry nitrogen was introduced to atmospheric pressure. 10 ml of toluene and 4 ml of NMP were then added and the mixture was stirred at 80° C. for 30 min (vessel A).

Meanwhile, 64 mg (0.17 mmol) of 2,5-bis(4-bromophenyl)-1,3,4-oxadiazole, 138 mg (0.33 mmol) of 2,2′-dibromo-1,1′-binaphthyl, and 646 mg (1.18 mmol) of 2,7-dibromo-9,9-diethylhexylfluorene were placed in a separate vacuum-dried vessel B under a dry nitrogen atmosphere. 6 ml of toluene were further added to dissolve the compounds. While care was taken to avoid contact with the air, the solution in the vessel B was transferred to the vessel A. Following stirring for 5 min, 220 mg (2.03 mmol) of 1,5-cyclooctadiene were added and the reaction was allowed to proceed at 80° C. for 3 days. Subsequently, as much of the solvent as possible was removed to obtain a viscous material.

This material was washed sequentially with 1N hydrochloric acid, 1N aqueous sodium hydroxide solution, and distilled water. The washed material was then dissolved in a small amount of THF and was re-precipitated twice in methanol to give 270 mg of the desired product. The results of GPC (eluant: THF, compared with polystyrene of known molecular weight) indicated that the polymer had a weight average molecular weight (Mw) of 22171 and a number average molecular weight (Mn) of 11162. The concentration of inorganic metal elements present in the polymer proved to be less than the detection limit of the energy dispersive x-ray analysis (EDX) (0.1%).

Evaluation

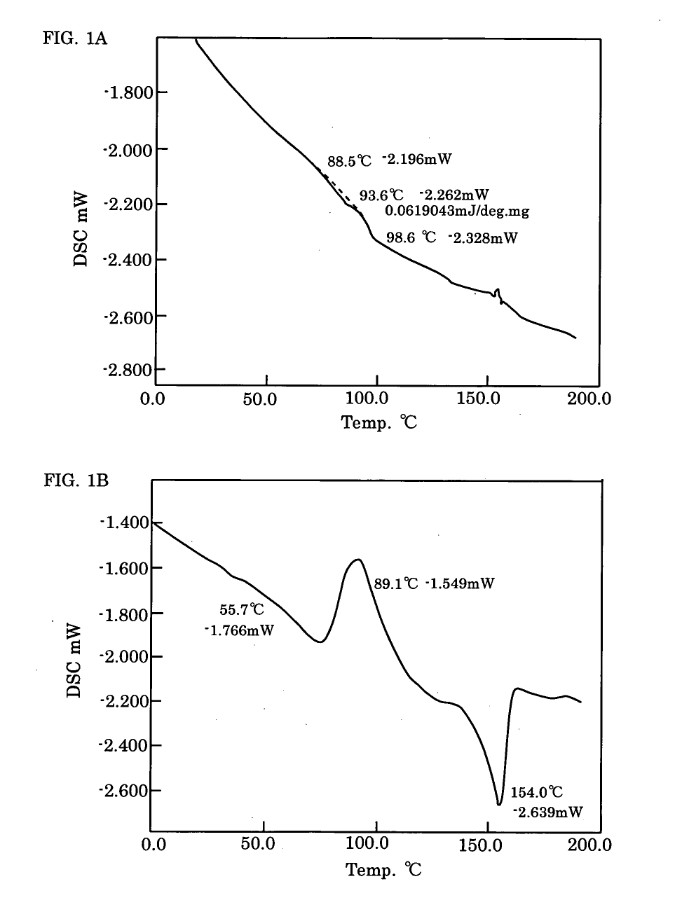

Differential Scanning Calorimetry (DSC, the rate of temperature increase=20° C./min, Reference=α-alumina) was conducted using the EL polymers obtained in Example 1 and Comparative Example 1. Specifically, the polymers were heated from room temperature to 180° C. under a nitrogen atmosphere and were immediately cooled to 0° C. in liquid nitrogen. Measurements were taken as the polymers were heated from 0° C. to 200° C. The results were shown in FIG. 1A for the EL polymer of Example 1 and in FIG. 1B for the EL polymer of Comparative Example 1.

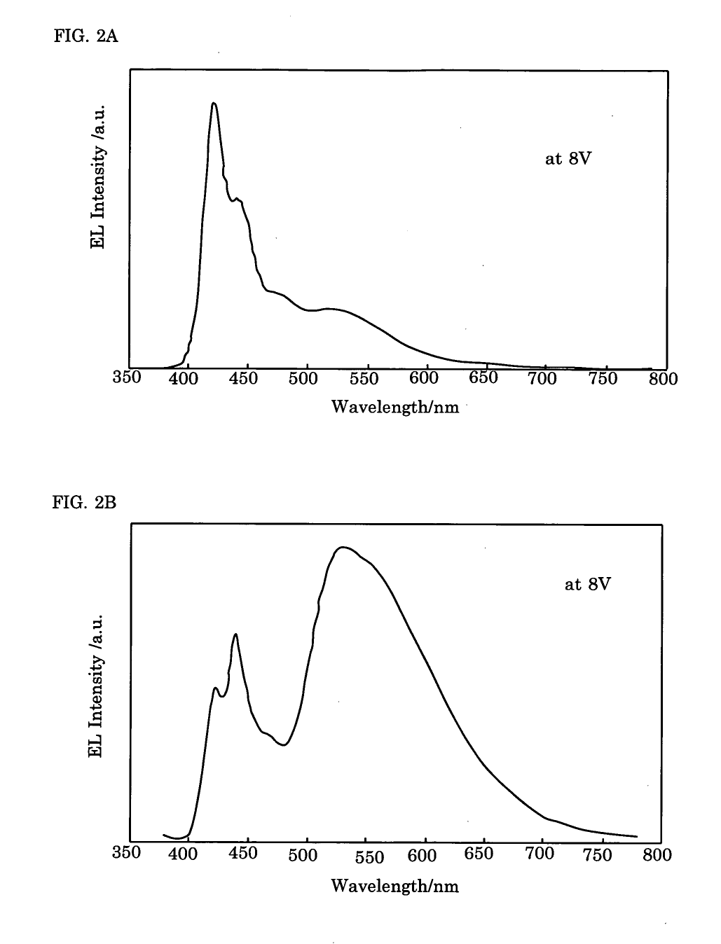

As described below, EL devices were constructed using the EL polymers obtained in Examples 1 through 4 and Comparative Examples 1 and 2. Using ordinary techniques, each EL device was examined for the EL characteristics, maximum current efficiency, and CIE color coordinates (Instrument used=original system incorporating spectroradiometer SR-3 manufactured by TOPCON Co., Ltd. and DC voltage power source/monitor manufactured by ADVANTEST Co., Ltd.) (EL spectrum were obtained for Example 1 and Comparative Example 1 only). The EL spectrum of the EL device constructed using the EL polymer of Example 1 is shown in FIG. 2A and the EL spectrum of the EL device constructed using the EL polymer of Comparative Example 1 is shown in FIG. 2B. The maximum luminance, maximum current efficiency, and CIE color coordinates of each device are shown in Table 1.

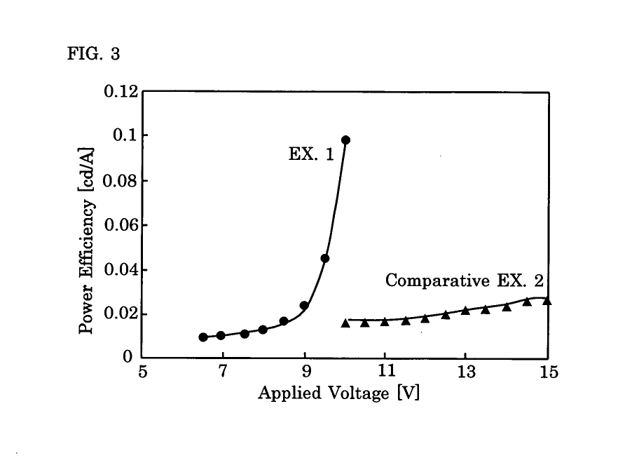

The organic EL devices constructed from the EL polymers obtained in Example 1 and Comparative Example 2 were examined for the efficiency of the luminescence over the applied voltage. The results are shown in FIG. 3.

(Preparation of Organic EL Device)

A glass substrate coated with indium-tin oxide (ITO) (200 nm thick, sheet resistance=10 Ω/sq or below, transmittance=80% or above) was sonicated using a commercially available detergent and was rinsed in a deionized water. The substrate was further sonicated with acetone and then isopropyl alcohol (IPA) and was immersed in boiled IPA to degrease. Subsequently, the substrate was exposed to excimer irradiation on an excimer radiator.

Using an RPM-controlled spin coater, a hole-transporting polymer (Baytron P(TP AI 4083) or Baytron P(VP CH8000), Bayer), filtered through a 0.20 μm pp filter, was applied to the substrate over the ITO surface and dried to a thickness of 70 nm. The substrate was then dried in a vacuum drier (100° C.×1 hour) to form a hole-transporting polymer layer.

Toluene solutions (1.0 wt %) of the EL polymers of Example 1 and Comparative Example 1 were each filtered through a 0.2 μm PTFE filter. Using an RPM-controlled spin coater, each polymer solution was applied to the glass substrate over the hole-transporting polymer layer to a thickness of 100 nm. The coating was then dried to form a luminescent layer.

Subsequently, calcium and then aluminum were deposited in vacuo (3×10⁻⁴ Pa or below) over the luminescent layer to thicknesses of 20 nm and 150 nm, respectively.

A voltage was applied to the resulting organic EL device so that the ITO side serves as a positive electrode and the aluminum side as a negative electrode. As a result, the device emitted light corresponding to electroluminescence (EL) (FIGS. 2A and 2B).

(Analysis of the Results)

As can been seen from FIG. 1B, the DSC plot of the polydioctylfluorene homopolymer of Comparative Example 1 has an inflection point (glass transition point) near 60° C. and a peak near 90° C. that is considered to result from the crystallization of the polymer. In contrast, the DSC plot of the octylfluorene-binaphthyl copolymer of Example 1 as shown in FIG. 1A has a shifted glass transition point near 90° C. and has no peaks.

Thus, it is considered that the EL polymer of Example 1, in which the rigid polymer backbone includes bends to cause considerable steric hindrance, shows a high solubility in solvents and hardly forms aggregates when film-formed. Although the structure of the EL polymer of Example 1 naturally leads to an expectation that the polymer has a decreased glass transition point, it in fact has a higher glass transition point than the polymer of Comparative Example 1, as shown in FIG. 1A. This suggests the possibility of the use of the EL polymer of Example 1 at higher temperatures. This is believed to be because the steric hindrance caused by the naphthalene rings prevents the rotation about the 1,1′-linkage in the binaphthyl residue. In addition, the disappearance of the crystallization peak implies that the structure of the EL polymer of Example 1 makes the rearrangement of the polymer molecules difficult. This offers an explanation to the stable EL characteristics of the organic EL device of Example 1.

As can been seen from the EL spectrum of FIG. 2B, the organic EL device constructed from the EL polymer of Comparative Example 1 emitted a significant amount of excimer light near 530 nm, whereas no significant excimer luminescence was observed near 540 nm in the organic EL device constructed from the EL polymer of Example 1, as shown by the EL spectrum of FIG. 2A.

FIG. 3 shows a comparison in the efficiency of EL luminescence between two dioctylfluorene polymers in which binaphthyl derivative structural units or biphenyl derivative structural units have been introduced to cause bends in the polymer backbones of dioctylfluorene structural units. As shown, the efficiency of EL luminescence was significantly higher in the dioctylfluorene polymer incorporating binaphthyl derivative structural units than in the dioctylfluorene polymer incorporating biphenyl derivative structural units. This is because the steric hindrance provided by the biphenyl derivative structural units is less than that provided by the binaphthyl derivative structural units. The reason for the less steric hindrance of the biphenyl derivative structural units is believed to be that the biphenyl derivative structural units have a relatively high degree of freedom of rotation about the 1,1-linkage and, thus, the distortion of the polymer chain can become so large that the conjugation of the polymer chain breaks, resulting in a reduced efficiency of EL luminescence.

TABLE 1

| | Maximum | Current | CIE color | Luminescence |
|---|---|---|---|---|
| | luminance | efficiency | coordinate | color |
| Example 1 | 361 cd/m² | 0.10 cd/A | (0.20, 0.22) | Blue |
| | (10 V) | (10 V) | (10 V) | |
| Comparative | 878 cd/m² | 1.1 cd/A | (0.34, 0.51) | Green |
| Example 1 | (10 V) | (10 V) | (10 V) | |
| Comparative | 72 cd/m² | 0.03 cd/A | (0.22, 0.31) | Light blue |
| Example 2 | (18 V) | (18 V) | (18 V) | |
| Example 2 | 545 cd/m² | 0.52 cd/A | (0.17, 0.15) | Deep blue |
| | (7.5 V) | (7.5 V) | (7.5 V) | |
| Example 3 | 512 cd/m² | 1.23 cd/A | (0.17, 0.16) | Deep blue |
| | (7.0 V) | (7.0 V) | (7.0 V) | |
| Example 4 | 9.0 cd/m² | 0.025 cd/A | (0.23, 0.32) | Light blue |
| | (27.5 V) | (27.5 V) | (27.5 V) | |
| Example 5 | 40 cd/m² | 0.022 cd/A | (0.19, 0.23) | Blue |
| | (7.5 V) | (7.5 V) | (10 V) | |
| Example 6 | 167 cd/m² | 0.224 cd/A | (0.21, 0.22) | Blue |
| | (7.5 V) | (7.5 V) | (7.5 V) | |
| Example 7 | 86 cd/m² | 0.044 cd/A | (0.21, 0.28) | Light blue |
| | (11.5 V) | (11.5 V) | (11.5 V) | |
| Example 8 | 259 cd/m² | 0.091 cd/A | (0.18, 0.16) | Deep blue |
| | (9.0 V) | (9.0 V) | (9.0 V) | |
| Example 9 | 370 cd/m² | 0.194 cd/A | (0.19, 0.16) | Deep blue |
| | (13.0 V) | (13.0 V) | (13.0 V) | |

As can be seen from the results of Table 1, the polyalkylfluorenes (such as 9,9-dioctylfluorene polymers and 9,9-diethylhexylfluorene polymers) are susceptible to morphological changes during or after film formation. The resulting formation of intermolecular complexes and other aggregates causes a shift of the color of the luminescence of fluorene from its original blue to green (red shift). For example, the CIE coordinates of Comparative Example 1 indicate green color (excimer luminescence) resulting from unstable morphology. The unstable morphology was also evidenced by the phase transition observed in DSC, as shown in FIGS. 1A and 1B, and by the comparison between the EL spactra of FIGS. 2A and 2B (The presence of excimer luminescence near 530 nm).

The introduction of binaphthyl derivative structural units into the electroluminescence polymer of the present invention results in a reduced interaction between molecular chains. As a result, these polymers emit the original blue color of fluorene. The results of Examples 1, 2, 3, 5, 6, 7, 8, and 9 are thus preferred. Of these, the EL polymers of Examples 2, 3, 8 and 9, each emitted deep blue light, are particularly preferred. The EL polymer of Example 4, which did not have fluorene backbone, also emitted blue light because of the absence of molecular chain interaction.

### INDUSTRIAL APPLICABILITY

The novel EL polymer of the present invention exhibit stable EL characteristics that are less susceptible to morphological changes after film of the polymer has been formed. For this reason, the EL polymer of the present invention is suitable for use in organic EL displays.

1. An electroluminescence polymer comprising a binaphthyl derivative structural unit represented by the following formula (1a) and an aryl structural unit represented by the following formula (1b):
wherein Ar is an aryl structural unit that can form an electroluminescent □-conjugated 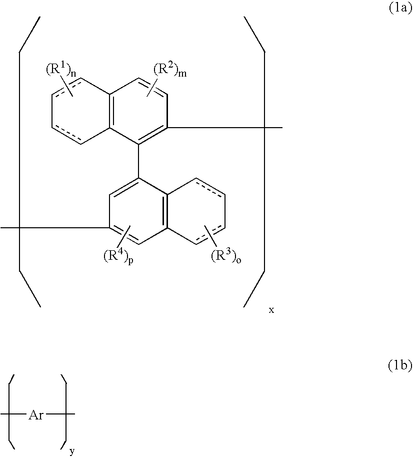
polymer; R¹, R², R³ and R⁴ are each independently hydrogen, alkyl, alkenyl, alkynyl, aralkyl, aryl, heteroaryl, alkoxyl, aryloxy or aliphatic heterocyclic group; the double bonds of the binaphthyl structural unit indicated by dashed lines and solid lines are each an unsaturated double bond or a saturated single bond; m and p are each independently 0, 1 or 2; n and o are each independently 0, 1, 2, 3, 4, 5, 6, 7 or 8; when m, n, o or p is an integer of 2 or greater, the two or more R¹s, R²s, R³s, or R⁴s may or may not be identical to one another; x is the molar fraction of the binaphthyl derivative structural units; and y is the molar fraction of the aryl structural units.

2. The electroluminescence polymer according to claim 1, wherein the binaphthyl derivative structural unit of the formula (1a) is a structural unit represented by the following formula (2): 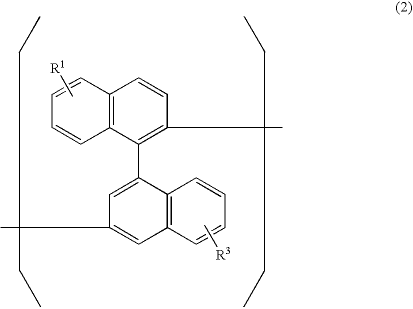
wherein R¹ and R³ are each independently hydrogen, alkyl, alkenyl, alkynyl, aralkyl, aryl, heteroaryl, alkoxyl, aryloxy, or aliphatic heterocyclic group.

3. The electroluminescence polymer according to claim 1, wherein the aryl structural unit of the formula (1b) is a fluorene derivative structural unit represented by the following formula (3): 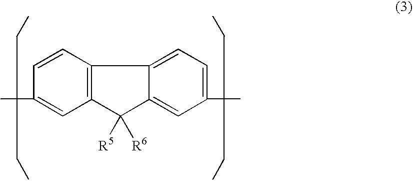
wherein R⁵ and R⁶ are each independently hydrogen, alkyl, alkenyl, alkynyl, aralkyl, aryl, heteroaryl, alkoxyl, aryloxy, or aliphatic heterocyclic group.

4. The electroluminescence polymer according to claim 1, wherein x is in a range of 0.1 to 90 mol %.

5. The electroluminescence polymer according to claim 3, comprising, in addition to the binaphthyl derivative structural unit and the fluorine derivative structural unit, at least one of carbazole derivative structural unit, anthracene derivative structural unit, naphthyl derivative structural unit, biphenyl derivative structural unit, benzene derivative structural unit, and aromatic heterocyclic derivative structural unit.

6. An organic electroluminescence device, comprising a luminescent layer sandwiched between a pair of electrodes, the luminescent layer formed of the electroluminescence polymer according to claim 1.

7. A display comprising the organic electroluminescence device according to claim 6.

8. The electroluminescence polymer according to claim 2, wherein x is in a range of 0.1 to 90 mol %.

9. The electroluminescence polymer according to claim 3, wherein x is in a range of 0.1 to 90 mol %.

10. An organic electroluminescence device, comprising a luminescent layer sandwiched between a pair of electrodes, the luminescent layer formed of the electroluminescence polymer according to claim 2.

11. An organic electroluminescence device, comprising a luminescent layer sandwiched between a pair of electrodes, the luminescent layer formed of the electroluminescence polymer according to claim 3.

12. An organic electroluminescence device, comprising a luminescent layer sandwiched between a pair of electrodes, the luminescent layer formed of the electroluminescence polymer according to claim 4.

13. An organic electroluminescence device, comprising a luminescent layer sandwiched between a pair of electrodes, the luminescent layer formed of the electroluminescence polymer according to claim 5.
